(19) United States
(12) Patent Application Publication
(10) Pub. No.: US 2024/0339435 A1
(43) Pub. Date: Oct. 10, 2024

(54) SEMICONDUCTOR PACKAGE INCLUDING CONTROL CHIP INCLUDING CHIP ENABLE SIGNAL CONTROL CIRCUIT

(71) Applicant: SK hynix Inc., Icheon-si Gyeonggi-do (KR)

(72) Inventor: Ki Yong LEE, Icheon-si Gyeonggi-do (KR)

(73) Assignee: SK hynix Inc., Icheon-si Gyeonggi-do (KR)

(21) Appl. No.: 18/477,364

(22) Filed: Sep. 28, 2023

(30) Foreign Application Priority Data
Apr. 6, 2023 (KR) 10-2023-0045698

(51) Int. Cl. H01L 25/065; H01L 23/00; H01L 25/18

(52) U.S. Cl. CPC H01L 25/0657; H01L 24/16; H01L 24/48; H01L 25/18; H01L 2224/16227; H01L 2224/48145; H01L 2224/48227; H01L 2225/0651; H01L 2924/1438

(57) ABSTRACT

A semiconductor package includes a package substrate, a plurality of memory chips stacked over the package substrate, and a control chip disposed over the package substrate to be spaced apart from the plurality of memory chips. The control chip includes a plurality of first chip enable signal control pads transmitting chip enable signals to and from the plurality of memory chips, a plurality of second chip enable signal control pads transmitting the chip enable signals to and from an external electronic device external to the semiconductor package, a chip enable signal control circuit configured to control transmission paths of the chip enable signals between the plurality of first chip enable signal control pads and the plurality of second chip enable signal control pads, and a third chip enable signal control pad receiving a path control signal from the external electronic device for controlling the chip enable signal control circuit.

### CROSS-REFERENCE TO RELATED APPLICATIONS

The present application claims priority under 35 U.S.C. 119 (a) to Korean Application No. 10-2023-0045698, filed on Apr. 6, 2023, which is incorporated herein by reference in its entirety.

### BACKGROUND

### 1. Technical Field

The present disclosure generally relates to a semiconductor package and, more particularly, to a semiconductor package including a control chip including a chip enable signal control circuit.

### 2. Related Art

As increase in capacity and miniaturization of semiconductor packages employed in electronic products progress, various multi-chip stack packages are being developed. As an example, a multi-chip stack package may refer to a semiconductor package in which two or more semiconductor chips, such as memory chips are stacked over a package substrate.

In the multi-chip stack package, in order to select and operate specific memory chips, among a plurality of memory chips, chip enable (CE) signals may be transmitted between the plurality of memory chips and an external electronic device. Each of the plurality of memory chips may include chip enable pads capable of transmitting and receiving the chip enable signals through the package substrate.

Meanwhile, transmission paths of the chip enable signals in the semiconductor package may be determined by a connection configuration between the chip enable pads of the plurality of memory chips and connecting pads of the package substrate and by an arrangement configuration of internal interconnections of the package substrate. That is, when manufacturing of the semiconductor package is completed, the transmission paths of the chip enable signals for the plurality of memory chips may be determined.

### SUMMARY

A semiconductor package according to an embodiment of the present disclosure may include a package substrate, a plurality of memory chips stacked over the package substrate, and a control chip disposed over the package substrate to be spaced apart from the plurality of memory chips. The control chip may include a plurality of first chip enable signal control pads transmitting chip enable signals to and from the plurality of memory chips, a plurality of second chip enable signal control pads transmitting the chip enable signals to and from an external electronic device external to the semiconductor package, a chip enable signal control circuit configured to control transmission paths of the chip enable signals between the plurality of first hip enable signal control pads and the plurality of second chip enable signal control pads, and a third chip enable signal control pad receiving a path control signal from the external electronic device for controlling the chip enable signal control circuit.

A semiconductor package according to another embodiment of the present disclosure may include a package substrate including a substrate body having first and second surfaces that are on opposite sides of each other, a plurality of memory chips stacked over the first surface of the substrate body, and a control chip disposed over the first surface of the substrate body and including a chip enable signal control circuit configured to control transmission paths of chip enable signals between the plurality of memory chips and an external electronic device outside the semiconductor package. The chip enable signal control circuit may include a plurality of input nodes receiving the chip enable signals from the plurality of memory chips, a plurality of bypass nodes, based on a path control signal transmitted from the external electronic device, controlling the transmission paths of the chip enable signals received from the plurality of input nodes, and a plurality of output nodes outputting the chip enable signals transmitted through the controlled transmission path.

### BRIEF DESCRIPTION OF THE DRAWINGS

FIG. 1 is a schematic cross-sectional diagram illustrating a semiconductor package according to an embodiment of the present disclosure.

FIG. 2 is a schematic block diagram illustrating a memory chip according to an embodiment of the present disclosure.

FIG. 3 is a schematic diagram illustrating a chip enable signal control circuit of a control chip according to an embodiment of the present disclosure.

FIG. 4 is a schematic diagram illustrating an operation of a chip enable signal control circuit of a control chip according to an embodiment of the present disclosure.

FIGS. 5A and 5B are schematic diagrams illustrating an operation of a chip enable signal control circuit of a control chip according to another embodiment of the present disclosure.

FIG. 6 is a schematic diagram illustrating an operation of a chip enable signal control circuit of a control chip according to another embodiment of the present disclosure.

FIG. 7 is a schematic diagram illustrating an operation of a chip enable signal control circuit of a control chip according to another embodiment of the present disclosure.

FIG. 8 is a schematic cross-sectional diagram of a semiconductor package according to another embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

Semiconductor chips such as a memory chip and a control chip described herein may mean that semiconductor substrates integrated with electronic circuits are separated from each other in the form of chips. The memory chip may refer to a chip in which memory circuits such as DRAM circuits, SRAM circuits, NAND flash memory circuits, NOR flash memory circuits, MRAM circuits, ReRAM circuits, FeRAM circuits, or PcRAM circuits are integrated. The control chip may refer to a logic chip or an ASIC chip in which a logic circuit is integrated on a semiconductor substrate.

The semiconductor package may include a package substrate on which the semiconductor chip is mounted. The package substrate may include at least one layer of integrated circuit patterns. For communication between the package substrate and the semiconductor chip, a connecting means such as a bonding wire or a bump may be used. The semiconductor package may be applied to various electronic information processing devices, for example, information communication devices such as portable terminals, bio or health care related electronic devices, wearable electronic devices, etc.

Same reference numerals refer to same devices throughout the specification. Even though a reference numeral might not be mentioned or described with reference to a drawing, the reference numeral may be mentioned or described with reference to another drawing. In addition, even though a reference numeral might not be shown in a drawing, it may be shown in other drawings.

The semiconductor packages according to embodiments of the present disclosure may each include a plurality of memory chips and a control chip, which are disposed over a package substrate. In the present disclosure, a method of controlling transmission paths of chip enable signals for selecting predetermined memory chips among the plurality of memory chips will be described.

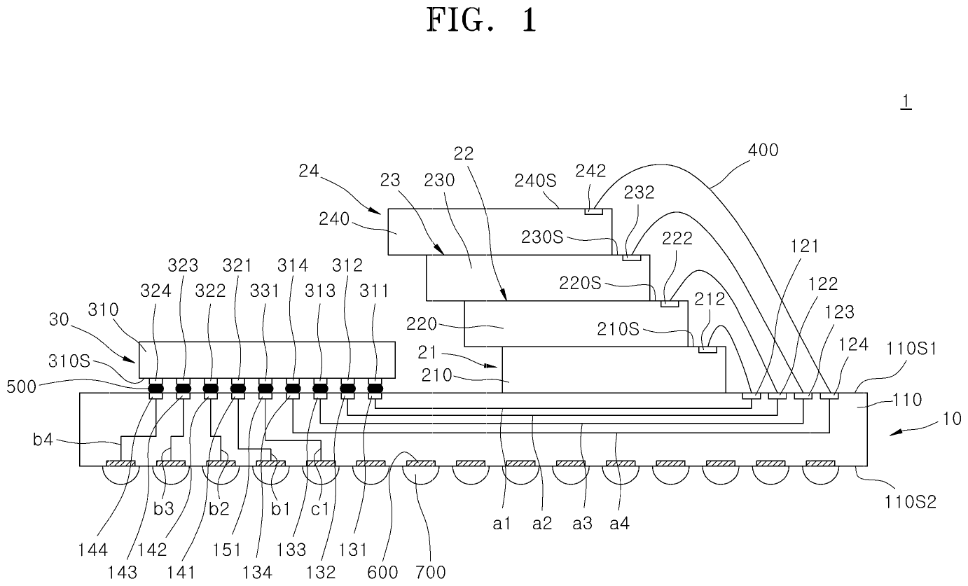

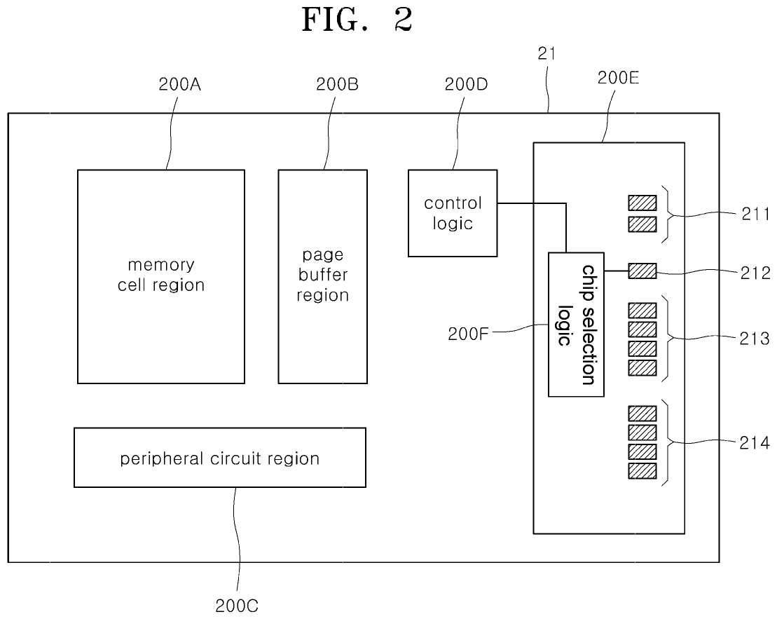

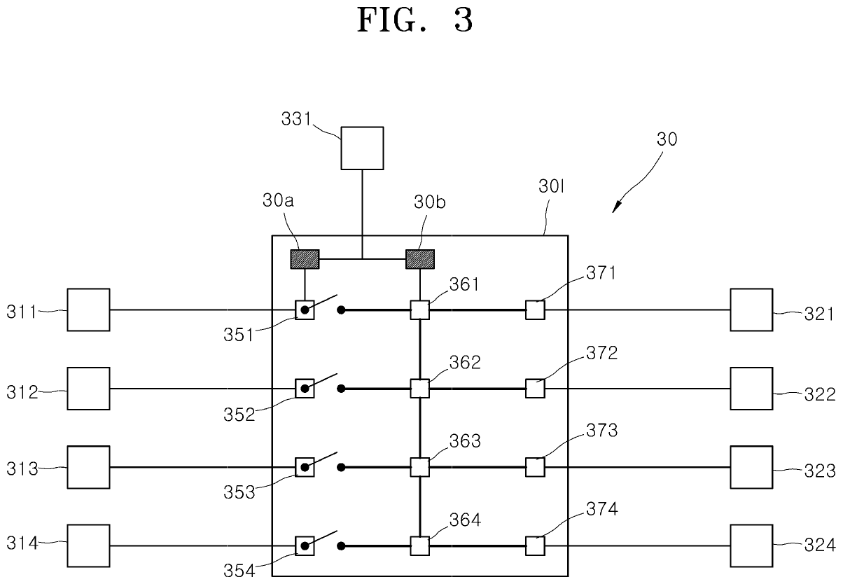

FIG. 1 is a schematic cross-sectional diagram illustrating a semiconductor package 1 according to an embodiment of the present disclosure. FIG. 2 is a schematic block diagram illustrating a memory chip according to an embodiment of the present disclosure. FIG. 3 is a schematic diagram illustrating a chip enable signal control circuit of a control chip according to an embodiment of the present disclosure.

Referring to FIG. 1, the semiconductor package 1 may include a package substrate 10, a plurality of memory chips 21, 22, 23, and 24 stacked over the package substrate 10, and a control chip 30 disposed over the package substrate 10 to be spaced apart from the plurality of memory chips 21, 22, 23, and 24.

The package substrate 10 may include a substrate body 110 having a first surface 110S1 and a second surface 110S2 that are on opposite sides of each other. The plurality of memory chips 21, 22, 23, and 24 may be disposed over the first surface 110S1 of the substrate body 110. Connecting lands 600 may be disposed on the second surface 110S2 of the substrate body 110 for electrically connecting with an external electronic device. Connecting structures 700, such as solder balls, may be disposed on the connecting lands 600.

In an embodiment, the semiconductor package 1 may include a first memory chip 21, a second memory chip 22, a third memory chip 23, and a fourth memory chip 24 as the plurality of memory chips 21, 22, 23, and 24. The first to fourth memory chips 21, 22, 23, and 24 may be substantially the same as each other. As an example, the first to fourth memory chips 21, 22, 23, and 24 may be DRAM chips. As an example, the first to fourth memory chips 21, 22, 23, and 24 may be NAND flash memory chips.

Referring to FIG. 1, the first memory chip 21 may include the first chip enable pad 212 disposed on an upper surface 210S of a chip body 210. The second memory chip 22 may be disposed on the first memory chip 21 to be off-set in a lateral direction with respect to the first memory chip 21 and may include the second chip enable pad 222 disposed on an upper surface 220S of a chip body 220. The third memory chip 23 may be disposed on the second memory chip 22 to be off-set in the lateral direction with respect to the second memory chip 22, the same lateral direction as the second memory chip 22 with respect to the first memory chip 21, and may include the third chip enable pad 232 disposed on an upper surface 220S of a chip body 230. The fourth memory chip 24 may be disposed on the third memory chip 23 to be off-set in the lateral direction with respect to the third memory chip 23, the same lateral direction as the third memory chip 23 with respect to the second memory chip 22, and may include the fourth chip enable pad 242 disposed on an upper surface 240S of a chip body 240.

A plurality of memory chip connecting fingers 121, 122, 123, and 124 may be disposed on the first surface 110S1 of the substrate body 110. As an example, first to fourth connecting fingers 121, 122, 123, and 124 may be disposed to be electrically connected to the first to fourth chip enable pads 212, 222, 232, and 242 of the first to fourth memory chips 21, 22, 23, and 24, respectively. The corresponding first to fourth chip enable pads 212, 222, 232, and 242 and the first to fourth connecting fingers 121, 122, 123, and 124 may be electrically connected to each other through bonding wires 400.

Referring to FIG. 1, the control chip 30 may be disposed over the first surface 110S1 of the substrate body 110 to be spaced apart from the first to fourth memory chips 21, 22, 23, and 24. The control chip 30 may be electrically connected to the package substrate 10 through flip-chip bonding.

The control chip 30 may include a chip body 310 and chip pads disposed on a surface 310S of the chip body 310, and the flip-chip bonding may be performed between the control chip 30 and the package substrate 10. In an embodiment, the control chip 30 may include a plurality of first chip enable signal control pads 311, 312, 313, and 314, a plurality of second chip enable signal control pads 321, 322, 323, and 324, and a third chip enable signal control pad 331.

The plurality of first chip enable signal control pads 311, 312, 313, and 314 may be divided into first to fourth control pads 311, 312, 313, and 314. The first to fourth control pads 311, 312, 313, and 314 may transmit the chip enable signals to and from the first to fourth memory chips 21, 22, 23, and 24, respectively. The plurality of second chip enable signal control pads 321, 322, 323, and 324 may be divided into fifth to eighth control pads 321, 322, 323, and 324. The fifth to eighth control pads 321, 322, 323, and 324 may transmit the chip enable signals to and from an external electronic device, external to the semiconductor package 1, through the package substrate 10. The third chip enable signal control pad 331 may receive a path control signal, transmitted from the external electronic device, through the package substrate 10.

Meanwhile, in the package substrate 10, substrate pads electrically connected to the chip pads of the control chip 30 may be disposed on the first surface 110S1 of the substrate body 110. The substrate pads may include a plurality of first control chip connecting pads 131, 132, 133, and 134, a plurality of second control chip connecting pads 141, 142, 143, and 144, and a third control chip connecting pad 151, which are electrically connected to the plurality of first chip enable signal control pads 311, 312, 313, and 314, the plurality of second chip enable signal control pads 321, 322, 323, and 324, and the third chip enable signal control pad 331, respectively, through connecting bumps 500.

In an embodiment, the plurality of first control chip connecting pads 131, 132, 133, 134 may be divided into first to fourth connecting pads 131, 132, 133, and 134. The first to fourth connecting pads 131, 132, 133, and 134 may be connected to the first to fourth control pads 311, 312, 313, and 314 of the control chip 30, respectively, and may be electrically connected to the first to fourth connecting fingers 121, 122, 123, and 124 through first substrate interconnections a1, a2, a3, and a4, respectively. Therefore, the plurality of first chip enable signal control pads 311, 312, 313, and 314 of the control chip 30 may transmit the chip enable signals to and from the first to fourth memory chips 21, 22, 23, and 24 through the package substrate 10.

In an embodiment, the plurality of second control chip connecting pads 141, 142, 143, and 144 may be divided into fifth to eighth connecting pads 141, 142, 143, and 144. The fifth to eighth connecting pads 141, 142, 143, and 144 may be connected to the fifth to eighth control pads 321, 322, 323, and 324 of the control chip 30, respectively, and may be electrically connected to corresponding connecting lands 600, among the plurality of connecting lands 600, through the corresponding substrate interconnections, among the second substrate interconnections b1, b2, b3, and b4. Therefore, the plurality of second chip enable signal control pads 311, 312, 313, and 314 of the control chip 30 may transmit the chip enable signals to and from an external electronic device, external to the semiconductor package 1, through the package substrate 10.

In an embodiment, the third control chip connecting pad 151 may be connected to the third chip enable signal control pad 331 and may be electrically connected to the corresponding connecting land, among the plurality of connecting lands 600, through a third substrate interconnection c1. Therefore, the third chip enable signal control pad 331 of the control chip 30 may receive the path control signal from the external electronic device through the package substrate 10.

Referring to FIG. 1, the connecting lands 600 may be disposed on the second surface 110S2 of the substrate body 110 for electrically connecting with the external electronic device. The connecting structures 700, such as solder balls, may be disposed on the connecting lands 600. In the semiconductor package 1, various signals including the chip enable signal and the path control signal may be transmitted to and from the external electronic device through the connecting lands 600 and the connecting structures 700.

Meanwhile, referring to FIG. 2, a configuration of the memory chip according to an embodiment of the present disclosure will be described based on the first memory chip 21. The configuration of each of the second to fourth memory chips 22, 23, and 24 may be substantially the same as that of the first memory chip 21.

The first memory chip 21 may include a memory cell region 200A, a page buffer region 200B, a peripheral circuit region 200C, a control logic 200D, and a pad region 200E. The pad region 200E may be disposed in a peripheral region of the first memory chip 21. Various types of chip pads for exchanging various types of signals with the package substrate 10 may be disposed in the pad region 200E. As an example, the chip pads may include power pads 211 for respectively outputting a power supply voltage Vcc and a ground voltage Vss, chip enable pads 212 for transmitting and receiving chip enable signals for chip selection, control pads 213 for receiving various control signals related to chip operation, and input/output (I/O) pads 214 for data input/output.

In addition, a chip selection logic 200F for transmitting the chip enable signal may be disposed between the chip enable pad 212 and the control logic 200D. Although not shown in FIG. 2, a circuit logic may be disposed in the pad region 200E for communicating between the power supply pads 211, control pads 213, and input/output (I/O) pads 214 and the control logic 200D.

Meanwhile, in the drawings and specification of the present disclosure, illustration for remaining chip pads other than the chip enable pads 212, 222, 232, and 242 are omitted among the chip pads of the first to fourth memory chips 21, 22, 23, and 24, and descriptions for the remaining chip pads are omitted. In addition, among the substrate pads disposed on the package substrate 10, illustration for the remaining substrate pads other than the substrate pads for transmitting and receiving the chip enable signal has been omitted, and descriptions for the remaining substrate pads have been omitted. In addition, when the control chip 30 is disposed over the package substrate 10, illustration for the control chip pads other than those related to the chip enable signal processing, among various control chip pads disposed over the control chip 30, has been omitted, and descriptions for the remaining control chip pads have been omitted. Known techniques may be applied to the configurations of the remaining chip pads, remaining substrate pads, and remaining control chip pads, which are not described.

Referring to FIG. 3, the control chip 30 may include a chip enable signal control circuit 30I. The chip enable signal control circuit 30I may be disposed inside the chip body 310 of FIG. 1 of the control chip 30. The chip enable signal control circuit 30I may control a transmission path of the chip enable signal for selecting a predetermined memory chip from among the plurality of memory chips 21, 22, 23, and 24 of FIG. 1, according to the path control signal transmitted from the external electronic device.

Referring to FIG. 3, the chip enable signal control circuit 30I may include a plurality of input nodes 351, 352, 353, and 354 that are electrically connected to the plurality of first chip enable signal control pads 311, 312, 313, and 314, respectively. The plurality of input nodes 351, 352, 353, and 354 may be divided into first to fourth input nodes 351, 352, 353, and 354. As described above, when the plurality of first chip enable signal control pads 311, 312, 313, and 314 are divided into the first to fourth control pads 311, 312, 313, and 314, the first to fourth input nodes 351, 352, 353, and 354 may transmit the chip enable signals to and from the first to fourth control pads 311, 312, 313, and 314, respectively.

In addition, the chip enable signal control circuit 30I may include a plurality of output nodes 371, 372, 373, and 374 that are electrically connected to the plurality of second chip enable signal control pads 321, 322, 323, and 324, respectively. The plurality of output nodes 371, 372, 373, and 374 may be divided into first to fourth output nodes 371, 372, 373, and 374, As described above, when the plurality of second chip enable signal control pads 321, 322, 323, and 324 are divided into the fifth to eighth control pads 321, 322, 323, and 324, the first to fourth output nodes 371, 372, 373, and 374 may be transmit the chip enable signals to and from the fifth to eighth control pads 321, 322, 323, and 324, respectively.

In addition, the chip enable signal control circuit 30I may include a plurality of bypass nodes 361, 362, 363, and 364 that receive the chip enable signal from the plurality of input nodes 351, 352, 353, and 354 and that transmit the received chip enable signal to the corresponding output node, among the plurality of output nodes 371, 372, 373, and 374. The plurality of bypass nodes 361, 362, 363, and 364 may be divided into first to fourth bypass nodes 361, 362, 363, and 364. Based on the path control signals transmitted from the third chip enable signal control pad 331, the first to fourth bypass nodes 361, 362, 363, and 364 may determine the output node outputting the chip enable signal.

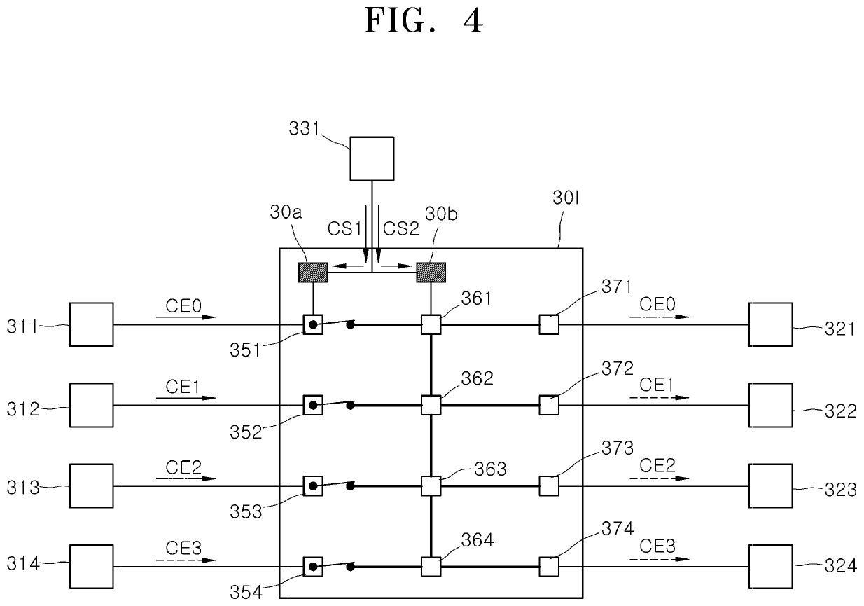

In an embodiment, the chip enable signal control circuit 30I may include first and second control nodes 30a and 30b receiving the path control signals from the third chip enable signal control pad 331. The first control node 30a may receive a first control signal from among the path control signals and may transmit the first control signal to the first to fourth input nodes 351, 352, 353, and 354. The second control node 30b may receive a second control signal from among the path control signals and may transmit the second control signal to the first to fourth bypass nodes 361, 362, 363, and 364. A control operation of the chip enable signal control circuit 30I of the control chip 30 will be described in more detail through the embodiments of FIGS. 4, 5A, 5B, 6, and 7.

FIG. 4 is a schematic diagram illustrating an operation of a chip enable signal control circuit of a control chip according to an embodiment of the present disclosure. FIG. 4 illustrates a method in which the chip enable control circuit 30I of the semiconductor package 1 of FIG. 1 controls transmission paths of the chip enable signals for the first to fourth memory chips 21, 22, 23, and 24 when the first to fourth memory chips 21, 22, 23, and 24 are good products.

Referring to FIG. 4, together with FIG. 1, it may be determined whether the first to fourth memory chips 21, 22, 23, and 24 are defective based on the electrical test results for the first to fourth memory chips 21, 22, 23, and 24 of the semiconductor package 1. When it is determined that all of the first to fourth memory chips 21, 22, 23, and 24 are good products, an external electronic device connected to the semiconductor package 1 may transfer path control signals CS1 and CS2 for chip enable signals CE0, CE1, CE2, and CE3 of the first to fourth memory chips 21, 22, 23, and 24 to the control chip 30 through the package substrate 10 of the semiconductor package 1. Specifically, the path control signals CS1 and CS2 may reach the connecting land 600 disposed on the second surface 110S2 of the substrate body 110 through the connecting structure 700 and then may reach the third control chip connecting pad 151 through the third substrate interconnection c1. Subsequently, the path control signals CS1 and CS2 may be input to the third chip enable signal control pad 331 of the control chip 30 through the connecting bump 500. Subsequently, as shown in FIG. 4, the first control signal CS1, between the path control signals CS1 and CS2, may be transmitted to the first control node 30a of the chip enable signal control circuit 30I, and the second control signal CS2 may be transmitted to the second control node 30b.

Referring to FIG. 4, the first to fourth input nodes 351, 352, 353, and 354 may receive the first to fourth chip enable signals CE0, CE1, CE2, and CE3 transmitted from the first to fourth control pads 311, 312, 313, and 314, respectively. In addition, the first to fourth input nodes 351, 352, 353, and 354 may receive the first control signal CS1 transmitted from the first control node 30a. The first control signal CS1 may include information indicating that all of the first to fourth memory chips 21, 22, 23, and 24 are good products. According to the first control signal CS1, the first to fourth input nodes 351, 352, 353, and 354 may transmit the received first to fourth chip enable signals CE0, CE1, CE2, and CE3 to the first to fourth bypass nodes 361, 362, 363, and 364, respectively.

The first to fourth bypass nodes 361, 362, 363, and 364 may receive the second control signal CS2 transmitted from the second control node 30b. The first to fourth bypass nodes 361, 362, 363, and 364 may transmit the received first to fourth chip enable signals CE0, CE1, CE2, and CE3 to the first to fourth output nodes 371, 372, 373, and 374, respectively, based on the second control signal CS2. The first to fourth output nodes 371, 372, 373, and 374 may output the first to fourth chip enable signals CE0, CE1, CE2, and CE3 to the fifth to eighth control pads 321, 322, 323, and 324, respectively.

As a result, referring to FIGS. 1 and 4 together, the first chip enable signal CE0 transmitted from the first chip enable pad 212 of the first memory chip 21 may be input to the first control pad 311 of the control chip 30 and then may be output to the package substrate 10 through the fifth control pad 321. The second chip enable signal CE1 transmitted from the second chip enable pad 222 of the second memory chip 22 may be input to the second control pad 312 of the control chip 30 and then may be output to the package substrate 10 through the sixth control pad 322. The third chip enable signal CE2 transmitted from the third chip enable pad 232 of the third memory chip 23 may be input to the third control pad 313 of the control chip 30 and then may be output to the package substrate 10 through the seventh control pad 323. The fourth chip enable signal CE3 transmitted from the fourth chip enable pad 242 of the fourth memory chip 24 may be input to the fourth control pad 314 of the control chip 30 and then may be output to the package substrate 10 through the eighth control pad 324.

The first to fourth chip enable signals CE0, CE1, CE2, and CE3 output from the package substrate 10 may reach the corresponding connecting lands 600 through the corresponding substrate interconnections, among the second substrate interconnections b1, b2, b3, and b4, respectively, and then may be transmitted to the external electronic device through the connecting structures 700.

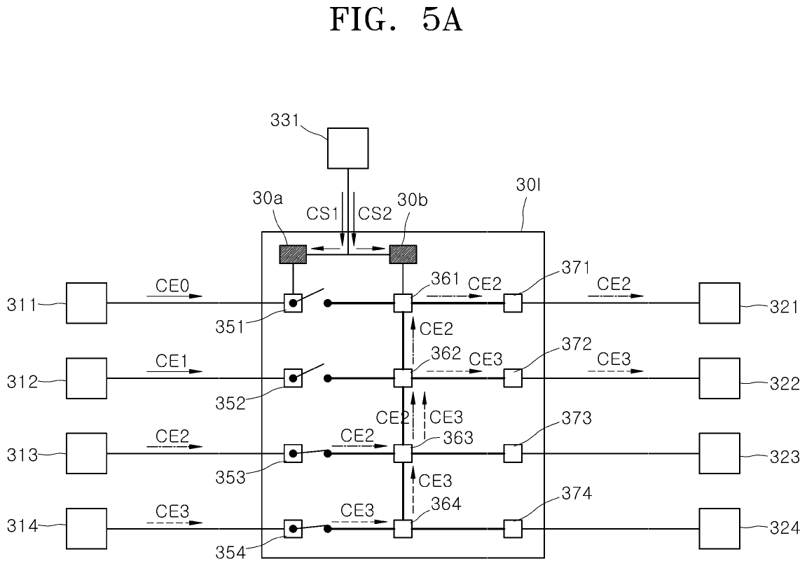

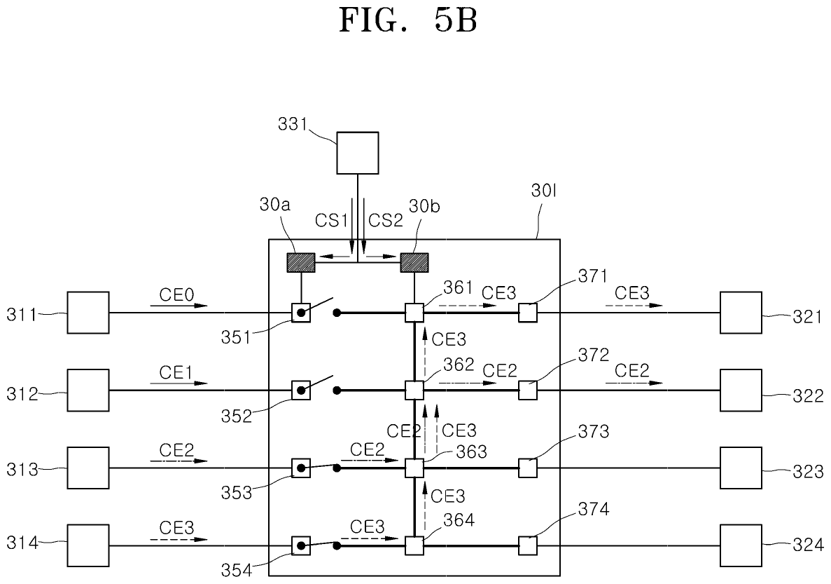

FIGS. 5A and 5B are schematic diagrams illustrating an operation of a chip enable signal control circuit of a control chip according to another embodiment of the present disclosure. Specifically, FIGS. 5A and 5B illustrate a method in which the chip enable control circuit 30I of the semiconductor package 1 of FIG. 1 controls the transmission paths of the chip enable signals for the first to fourth memory chips 21, 22, 23, and 24 when the first and second memory chips 21 and 22 are defective, among the first to fourth memory chips 21, 22, 23, and 24.

Referring to FIG. 5A, the first to fourth input nodes 351, 352, 353, and 354 may receive the first to fourth chip enable signals CE0, CE1, CE2, and CE3 transmitted from the first to fourth control pads 311, 312, 313, and 314, respectively. In addition, the first to fourth input nodes 351, 352, 353, and 354 may receive the first control signal CS1 transmitted from the first control node 30a. The first control signal CS1 may include information indicating that the first and second memory chips 21 and 22 are defective.

The first and second input nodes 351 and 352 may block the first and second chip enable signals CE0 and CE1 transmitted from the first and second memory chips 21 and 22 from being transmitted to the first and second bypass nodes 361 and 362, according to the first control signal CS1. The third and fourth input nodes 353 and 354 may transmit the third and fourth chip enable signals CE2 and CE3 to the third and fourth bypass nodes 363 and 364, respectively.

Meanwhile, the first and second bypass nodes 361 and 362 might not receive the first and second chip enable signals CE0 and CE1 from the first and second input nodes 351 and 352, respectively, and the third and fourth bypass nodes 363 and 364 may receive the third and fourth chip enable signals CE2 and CE3 from the third and fourth input nodes 353 and 354, respectively.

The first to fourth bypass nodes 361, 362, 363, and 364 may receive the second control signal CS2 from the second control node 30b. The second control signal CS2 may include information regarding the output node to which the third and fourth chip enable signals CE2 and CE3 received by the third and fourth bypass nodes 363 and 364 are transmitted.

The first to fourth bypass nodes 361, 362, 363, and 364 may assign the output nodes to which the third and fourth chip enable signals CE2 and CE3 are transmitted, according to the second control signal CS2. In an embodiment, the output nodes may be consecutively and sequentially assigned from the highest priority node. As an example, as for the output nodes, the first output node 371, which is the highest priority node, may be preferentially selected, and the second output node 372 disposed consecutively adjacent to the first output node 371 may be sequentially selected. That is, one of the third chip enable signal CE2 and the fourth chip enable signal CE3 is preferentially transmitted to the first output node 371, and then the other of the third chip enable signal CE2 and the fourth chip enable signal CE3 is transmitted to the second output node 382.

In an embodiment, as shown in FIG. 5A, the third chip enable signal CE2 may be transmitted to the first output node 371 via the third bypass node 363, the second bypass node 362, and the first bypass node 361, sequentially. The fourth chip enable signal CE3 may be transmitted to the second output node 372 via the fourth bypass node 364, the third bypass node 363, and the second bypass node 362, sequentially. Subsequently, the third and fourth chip enable signals CE2 and CE3 may be output from the first and second output nodes 371 and 372 to the fifth and sixth control pads 321 and 322, respectively.

In another embodiment, as shown in FIG. 5B, the third chip enable signal CE2 may be transmitted to the second output node 372 via the third bypass node 363 and the second bypass node 362, sequentially. The fourth chip enable signal CE3 may be transmitted to the first output node 371 via the fourth bypass node 364, the third bypass node 363, the second bypass node 362, and the first bypass node 361, sequentially. Subsequently, the third chip enable signal CE2 may be output from the second output node 372 to the sixth control pad 322, and the fourth chip enable signal CE3 may be output from the first output node 371 to the fifth control pad 321.

Through the above-described transmission method of the chip enable signals, even though defects occur in the first and second memory chips 21 and 22 of the semiconductor package 1, the chip selection operation for the third and fourth memory chips 23 and 24 using the third and fourth chip enable signals CE2 and CE3 may be effectively performed.

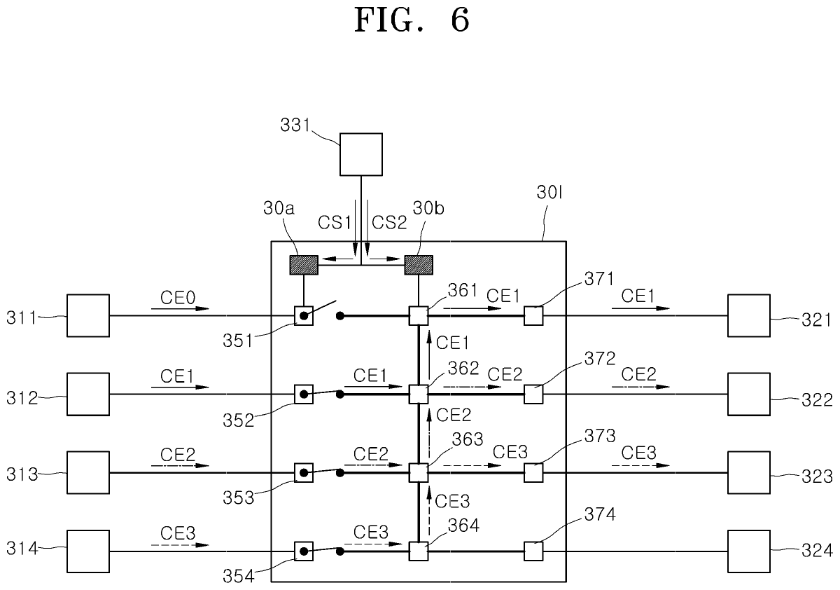

FIG. 6 is a schematic diagram illustrating an operation of a chip enable signal control circuit of a control chip according to another embodiment of the present disclosure. FIG. 6 illustrates a method in which the chip enable control circuit 30I of the semiconductor package 1 of FIG. 1 controls the transmission paths of the chip enable signals with respect to the first to fourth memory chips 21, 22, 23, and 24 when the first memory chip 21 is defective, among the first to fourth memory chips 21, 22, 23, and 24.

Referring to FIG. 6, together with FIG. 1, the first to fourth input nodes 351, 352, 353, and 354 may receive the first to fourth chip enable signals CE0, CE1, CE2, and CE3 transmitted from the first to fourth control pads 311, 312, 313, and 314, respectively. In addition, the first to fourth input nodes 351, 352, 353, and 354 may receive the first control signal CS1 including information indicating that the first memory chip 21 is defective from the first control node 30a.

The first input node 351 may block the first chip enable signal CE0 transmitted from the first memory chip 21 from being transmitted to the first bypass node 361, according to the first control signal CS1. The second to fourth input nodes 352, 353, and 354 may transmit the second to fourth chip enable signals CE1, CE2, and CE3 to the second to fourth bypass nodes 363, 363, and 364, respectively.

The first to fourth bypass nodes 361, 362, 363, and 364 may assign the output nodes to which the second to fourth chip enable signals CE1, CE2, and CE3 received from the second to fourth input nodes 352, 353, and 354 are output, according to the second control signal CS2.

In an embodiment, as shown in FIG. 6, for the output nodes, the first output node 371, which is the highest priority node, may be preferentially selected, and the second and third output nodes 372 and 373 disposed consecutively adjacent to the first output node 371 may be sequentially selected. Subsequently, the second to fourth chip enable signals CE1, CE2, and CE3 may be assigned to the first to third output nodes 371, 372, and 373, respectively.

In an embodiment, FIG. 6 illustrates the method in which the second chip enable signal CE1 is transmitted to the first output node 371, the third chip enable signal CE2 is transmitted to the second output node 372, and the fourth chip enable signal CE3 is transmitted to the third output node 373. However, the inventive spirit of the present disclosure is not limited thereto, and another method in which the second to fourth chip enable signals CE1, CE2, and CE3 are assigned to the first to third output nodes 371, 372, and 373, respectively, may be possible. That is, the number of cases in which the second to fourth chip enable signals CE1, CE2, and CE3 are assigned to the first to third output nodes 371, 372, and 373 is possible in six different ways.

According to the above-described six ways, the second to fourth chip enable signals CE1, CE2, and CE3 transmitted to the first to third output nodes 371, 372, and 373 may be output to the corresponding fifth to seventh control pads 321, 322, and 323, respectively.

Through the above-described transmission method of the chip enable signal, even though the first memory chip 21 of the semiconductor package 1 is defective, the chip selection operation for the second to fourth memory chips 22, 23, and 24 using the second to fourth chip enable signals CE1, CE2, and CE3 may be effectively performed.

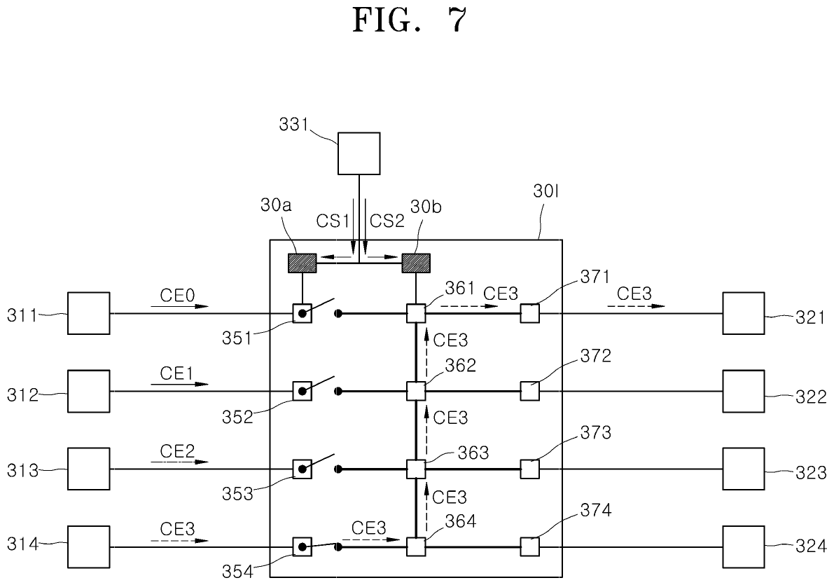

FIG. 7 is a schematic diagram illustrating an operation of a chip enable signal control circuit of a control chip according to another embodiment of the present disclosure. Specifically, FIG. 7 illustrates a method in which the chip enable control circuit 30I of the semiconductor package 1 of FIG. 1 controls the transmission paths of the chip enable signals for the first to fourth memory chips 21, 22, 23, and 24 when the first to third memory chips 21, 22, and 23 are defective, among the first to fourth memory chips 21, 22, 23, and 24.

Referring to FIG. 7, together with FIG. 1, the first to fourth input nodes 351, 352, 353, and 354 may receive the first to fourth chip enable signals CE0, CE1, CE2, and CE3 transmitted from the first to fourth control pads 311, 312, 313, and 314, respectively. In addition, the first to fourth input nodes 351, 352, 353, and 354 may receive the first control signal CS1 including information indicating that the first to third memory chips 21, 22, and 23 are defective from the first control node 30a.

The first to third input nodes 351, 352, and 353 may block the first to third chip enable signals CE0, CE1, and CE2 transmitted from the first to third memory chips 21, 22, and 23 from being transmitted to the first third bypass nodes 361, 362, and 363, respectively, according to the first control signal CS1. The fourth input node 354 may transmit the fourth chip enable signal CE3 to the fourth bypass node 364.

The first to fourth bypass nodes 361, 362, 363, and 364 may assign the output node to which the fourth chip enable signal CE3 received from the fourth input node 354 is output, according to the second control signal CS2.

In an embodiment, as shown in FIG. 7, for the output node, the first output node 371, which is the highest priority node, may be preferentially selected. Accordingly, the fourth chip enable signal CE3 may be transmitted to the first output node 371 via the fourth bypass node 364, the third bypass node 363, the second bypass node 362, and the first bypass node 361, sequentially, and the fourth chip enable signal CE3 may be output to the fifth control pad 321.

Through the above-described transmission method of the chip enable signals, even though defects occur in the first to third memory chips 21, 22, and 23 of the semiconductor package 1, the chip selection operation for the fourth memory chip 24 using the fourth chip enable signal CE3 may be effectively performed.

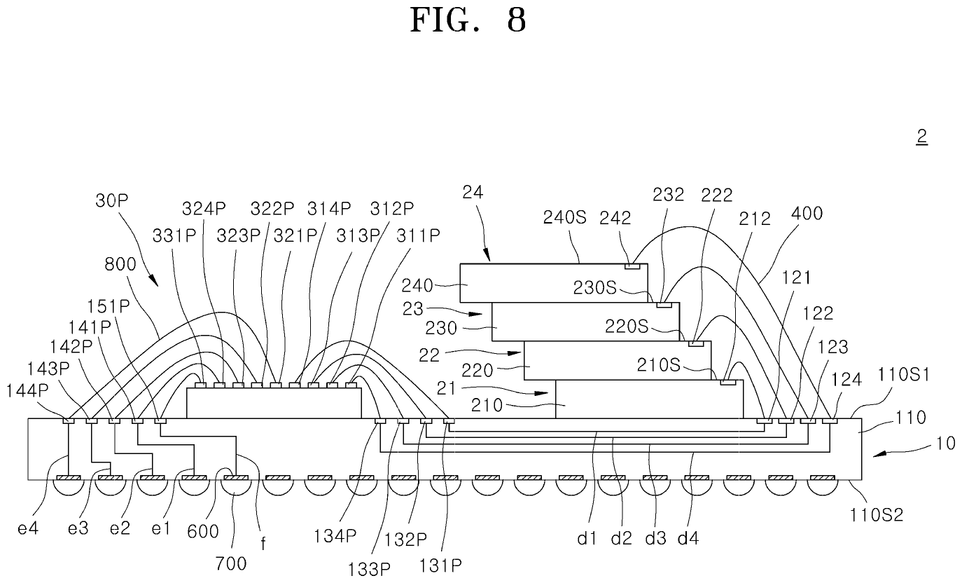

FIG. 8 is a schematic cross-sectional diagram of a semiconductor package 2 according to another embodiment of the present disclosure. Compared to the semiconductor package 1 of FIG. 1, the semiconductor package 2 of FIG. 8 may be different from the semiconductor package 1 in that a control chip 30P and a package substrate 10 are bonded by wire-bonding. Hereinafter, in order to avoid duplicate description, for the configuration of the semiconductor package 2, the configuration different from that of the semiconductor package 1 will be mainly described.

Referring to FIG. 8, the control chip 30P may be disposed over a first surface 110S1 of a substrate body 110 to be spaced apart from first to fourth memory chips 21, 22, 23, and 24.

The control chip 30P may include a plurality of first chip enable signal control pads 311P, 312P, 313P, and 314P, a plurality of second chip enable signal control pads 321P, 322P, 323P, and 324P, and a third chip enable signal control pad 331P. Functions of the plurality of first chip enable signal control pads 311P, 312P, 313P, and 314P, the plurality of second chip enable signal control pads 321P, 322P, 323P, and 324P, and the third chip enable signal control pad 331P may be substantially the same as those of the plurality of first chip enable signal control pads 311, 312, 313, and 314, the plurality of second chip enable signal control pads 321, 322, 323, 324, and the third chip enable signal control pad 331 of the semiconductor package 1 of FIG. 1, respectively.

A plurality of first control chip connecting fingers 131P, 132P, 133P, and 134P may be disposed on the first surface 110S1 of the substrate body 110 to correspond to the plurality of first chip enable signal control pads 311P, 312P, 313P, and 314P. The plurality of first control chip connecting fingers 131P, 132P, 133P, and 134P may be electrically connected to the plurality of first chip enable signal control pads 311P, 312P, 313P, and 314P through bonding wires 800, respectively. In addition, the plurality of first control chip connecting fingers 131P, 132P, 133P, and 134P may be electrically connected to a plurality of memory chip connecting fingers 121, 122, 123, and 124 through first substrate interconnections d1, d2, d3, and d4, respectively.

Similarly, corresponding to the plurality second chip enable signal control pads 321P, 322P, 323P, and 324P, a plurality of second control chip connecting fingers 141P, 142P, 143P, and 144P may be disposed on the first surface 110S1 of the substrate body 110. The plurality of second control chip connecting fingers 141P, 142P, 143P, and 144P may be electrically connected to the plurality second chip enable signal control pads 321P, 322P, 323P, and 324P by the bonding wires 800, respectively. In addition, the plurality of second control chip connecting fingers 141P, 142P, 143P, and 144P may be electrically connected to the corresponding connecting lands, among a plurality of connecting lands 600, through second substrate interconnections e1, e2, e3, and e4, respectively.

Similarly, corresponding to the plurality third chip enable signal control pad 331P, a third control chip connecting finger 151P may be disposed on the first surface 110S1 of the substrate body 110. The third control chip connecting finger 151P may be electrically connected to the third chip enable signal control pad 331P by the bonding wire 800. In addition, the third control chip connecting finger 151P may be electrically connected to the corresponding connecting land among the plurality of connecting lands 600 through a third substrate interconnection f.

As describe above, the control chip 30P of the semiconductor package 2 may be electrically connected to the package substrate 10 through a wire-bonding method. The control chip 30P may include the chip enable signal control circuit that may control transmission paths of the chip enable signals of the plurality of memory chips 21, 22, 23, and 24. The configuration and operation of the chip enable signal control circuit may be substantially the same as the configuration and operation of the chip enable signal control circuit 30I of the semiconductor package 1 of FIG. 1.

As describe above, various embodiments of the present disclosure may provide various methods of controlling the transmission paths of the chip enable signals of the plurality of memory chips using the chip enable signal control circuit of the control chip. Although, for convenience of description in the specification, the plurality of memory chips are limited to four memory chips, the inventive spirit of the present disclosure is not limited thereto, and may be applied to various numbers of memory chips, for the plurality of memory chips.

The inventive concept has been disclosed in conjunction with some embodiments as described above. Those skilled in the art will appreciate that various modifications, additions and substitutions are possible, without departing from the scope and spirit of the present disclosure. Accordingly, the embodiments disclosed in the present specification should be considered from not a restrictive standpoint but an illustrative standpoint. The scope of the inventive concept is not limited to the above descriptions but defined by the accompanying claims, and all of distinctive features in the equivalent scope should be construed as being included in the inventive concept.

What is claimed is:

1. A semiconductor package comprising:
a package substrate;
a plurality of memory chips stacked over the package substrate; and
a control chip disposed over the package substrate to be spaced apart from the plurality of memory chips,
wherein the control chip includes:
a plurality of first chip enable signal control pads transmitting chip enable signals to and from the plurality of memory chips;
a plurality of second chip enable signal control pads transmitting the chip enable signals to and from an external electronic device external to the semiconductor package;
a chip enable signal control circuit configured to control transmission paths of the chip enable signals between the plurality of first chip enable signal control pads and the plurality of second chip enable signal control pads; and
a third chip enable signal control pad receiving a path control signal from the external electronic device for controlling the chip enable signal control circuit.

2. The semiconductor package of claim 1, wherein the chip enable signal control circuit includes:
a plurality of input nodes electrically connected to the plurality of first chip enable signal control pads;
a plurality of output nodes electrically connected to the plurality of second chip enable signal control pads; and
a plurality of bypass nodes receiving the chip enable signals from the plurality of input nodes and transmitting the received chip enable signals to corresponding output nodes, among the plurality of output nodes, and
wherein the corresponding output nodes are determined based on the path control signal input from the third chip enable signal control pad into the plurality of bypass nodes.

3. The semiconductor package of claim 2,
wherein at least one of the plurality of input nodes blocks the chip enable signal, input from a corresponding memory chip, among the plurality of memory chips, from being transmitted to the plurality of bypass nodes according to the path control signal, and
wherein the plurality of bypass nodes receive the chip enable signals transmitted through the input nodes except for the at least one of the plurality of input nodes and assign the plurality of output nodes to which the received chip enable signals are output.

4. The semiconductor package of claim 3, wherein the plurality of output nodes are consecutively and sequentially assigned from a highest priority node.

5. The semiconductor package of claim 3, wherein the plurality of second chip enable signal control pads receive the chip enable signals through the assigned output nodes and transmit the chip enable signals to the package substrate.

6. The semiconductor package of claim 1,
wherein each of the plurality of memory chips includes a chip body and includes chip enable pads disposed on an upper surface of the chip body to transmit the chip enable signals to the package substrate, and
wherein the package substrate includes:
a substrate body having first and second surfaces that are on opposite sides of each other;
a plurality of memory chip connecting fingers disposed on the first surface of the substrate body and electrically connected to the chip enables pads of the plurality of memory chips;
a plurality of first control chip connecting pads, a plurality of second control chip connecting pads, and a third control chip connecting pad that are disposed on the first surface of the substrate body and electrically connected to the plurality of first chip enable signal control pads, the plurality of second chip enable signal control pads, and the third chip enable signal control pad, respectively; and
a plurality of connecting lands disposed on the second surface of the substrate body electrically connect with the external electronic device.

7. The semiconductor package of claim 6, further comprising:
bonding wires electrically connecting the chip enable pads of the plurality of memory chips to the plurality of memory chip connecting fingers of the package substrate;
first substrate interconnections electrically connecting the plurality of memory chip connecting fingers to the plurality of first control chip connecting pads;
second substrate interconnections electrically connecting the plurality of second control chip connecting pads to corresponding connecting lands, among the plurality of connecting lands;
a third substrate interconnection electrically connecting the third control chip connecting pad to a corresponding connecting land; and
connecting bumps electrically connecting the plurality of first chip enable signal control pads, the plurality of second chip enable signal control pads, and the third chip enable signal control pad to the plurality of first control chip connecting pads, the plurality of second control chip connecting pads, and the third control chip connecting pad, respectively.

8. The semiconductor package of claim 1,
wherein each of the plurality of memory chips includes a chip body and includes chip enable pads disposed on a surface of the chip body to transmit the chip enable signals to the package substrate, and
wherein the package substrate includes:
a substrate body having first and second surfaces that are on opposite sides of each other;
a plurality of memory chip connecting fingers disposed on the first surface of the substrate body and electrically connected to the chip enable pads of the plurality of memory chips;
a plurality of first control chip connecting fingers, a plurality of second control chip connecting fingers, and a third control chip connecting finger which are disposed on the first surface of the substrate body and electrically connected to the plurality of first chip enable signal control pads, the plurality of second chip enable signal control pads, and the third chip enable signal control pad, respectively; and
a plurality of connecting lands disposed on the second surface of the substrate body to electrically connect with the external electronic device.

9. The semiconductor package of claim 8, further comprising:
first bonding wires electrically connecting the chip enable pads of the plurality of memory chips to the plurality of memory chip connecting fingers of the package substrate;
first substrate interconnections electrically connecting the plurality of memory chip connecting fingers to the plurality of first control chip connecting fingers;
second substrate interconnections electrically connecting the plurality of second control chip connecting fingers to corresponding connecting lands, among the plurality of connecting lands;
a third substrate interconnection electrically connecting the third control chip connecting finger to a corresponding connecting land, among the plurality of connecting lands; and
second bonding wires electrically connecting the plurality of first chip enable signal control pads, the plurality of second chip enable signal control pads, and the third chip enable signal control pad to the plurality of first control chip connecting fingers, the plurality of second control chip connecting fingers, and the third control chip connecting finger, respectively.

10. The semiconductor package of claim 1, wherein the plurality of memory chips are NAND flash memory chips.

11. A semiconductor package comprising:
a package substrate including a substrate body having first and second surfaces that are on opposite sides of each other;
a plurality of memory chips stacked over the first surface of the substrate body; and
a control chip disposed over the first surface of the substrate body and including a chip enable signal control circuit configured to control transmission paths of chip enable signals between the plurality of memory chips and an external electronic device outside the semiconductor package,
wherein the chip enable signal control circuit includes:
a plurality of input nodes receiving the chip enable signals from the plurality of memory chips;
a plurality of bypass nodes, based on a path control signal transmitted from the external electronic device, controlling the transmission paths of the chip enable signals received from the plurality of input nodes; and
a plurality of output nodes outputting the chip enable signals transmitted to the package substrate by the plurality of bypass nodes through the controlled transmission path.

12. The semiconductor package of claim 11,
wherein at least one of the plurality of input nodes blocks the chip enable signal, input from a corresponding memory chip, among the plurality of memory chips, from being transmitted to the plurality of bypass nodes according to the path control signal, and
wherein the plurality of bypass nodes receive the chip enable signals transmitted through the input nodes except for the at least one of the plurality of input nodes and assign the plurality of output nodes to which the received chip enable signals are output.

13. The semiconductor package of claim 11, wherein the plurality of output nodes are consecutively and sequentially assigned from a highest priority node.

14. The semiconductor package of claim 11, wherein the control chip includes:
a plurality of first chip enable signal control pads electrically connected to the plurality of input nodes and transmitting the chip enable signals to and from the plurality of memory chips;
a plurality of second chip enable signal control pads electrically connected to the plurality of output nodes and transmitting the chip enable signals to and from the external electronic device; and
a third chip enable signal control pad receiving the path control signal transmitted from the external electronic device.

15. The semiconductor package of claim 14,
wherein each of the plurality of memory chips includes a chip body and includes chip enable pads disposed on an upper surface of the chip body to transmit and receive the chip enable signals, and
wherein the package substrate includes:
a plurality of memory chip connecting fingers disposed on the first surface of the substrate body and electrically connected to the chip enable pads of the plurality of memory chips;
a plurality of first control chip connecting pads, a plurality of second control chip connecting pads, and a third control chip connecting pad which are disposed on the first surface of the substrate body and electrically connected to the plurality of first chip enable signal control pads, the plurality of second chip enable signal control pads, and the third chip enable signal control pad, respectively; and
a plurality of connecting lands disposed on the second surface of the substrate body to electrically connect with the external electronic device.

16. The semiconductor package of claim 15, further comprising:
first bonding wires electrically connecting the chip enable pads of the plurality of memory chips to the plurality of memory chip connecting fingers of the package substrate;
first substrate interconnections electrically connecting the plurality of memory chip connecting fingers to the plurality of first control chip connecting pads;
second substrate interconnections electrically connecting the plurality of second control chip connecting pads to corresponding connecting lands, among the plurality of connecting lands;
a third substrate interconnection electrically connecting the third control chip connecting pad to a corresponding connecting land, among the plurality of connecting lands; and
connecting bumps electrically connecting the plurality of first chip enable signal control pads, the plurality of second chip enable signal control pads, and the third chip enable signal control pad to the plurality of first control chip connecting pads, the plurality of second control chip connecting pads, and the third control chip connecting pad, respectively.

17. The semiconductor package of claim 14,
wherein each of the plurality of memory chips includes a chip body, and chip enable pads disposed on an upper surface of the chip body to transmit the chip enable signals, and
wherein the package substrate includes:
a substrate body having first and second surfaces that are on opposite sides of each other;
a plurality of memory chip connecting fingers disposed on the first surface of the substrate body and electrically connected to the chip enables pads of the plurality of memory chips;
a plurality of first control chip connecting fingers, a plurality of second control chip connecting fingers, and a third control chip connecting finger which are disposed on the first surface of the substrate body and electrically connected to the plurality of first chip enable signal control pads, the plurality of second chip enable signal control pads, and the third chip enable signal control pad, respectively; and
a plurality of connecting lands disposed on the second surface of the substrate body to electrically connect with the external electronic device.

18. The semiconductor package of claim 17, further comprising:
first bonding wires electrically connecting the chip enable pads of the plurality of memory chips to the plurality of memory chip connecting fingers of the package substrate;
first substrate interconnections electrically connecting the plurality of memory chip connecting fingers to the plurality of first control chip connecting fingers;
second substrate interconnections electrically connecting the plurality of second control chip connecting fingers to corresponding connecting lands, among the plurality of connecting lands;
a third substrate interconnection electrically connecting the third control chip connecting finger to a corresponding connecting land, among the plurality of connecting lands; and
second bonding wires electrically connecting the plurality of first chip enable signal control pads, the plurality of second chip enable signal control pads, and the third chip enable signal control pad to the plurality of first control chip connecting fingers, the plurality of second control chip connecting fingers, and the third control chip connecting finger, respectively.

19. The semiconductor package of claim 11, wherein the plurality of memory chips are NAND flash memory chips.
